(19) United States
(12) Patent Application Publication
(10) Pub. No.: US 2025/0156016 A1
(43) Pub. Date: May 15, 2025

(54) INPUT SENSING PART AND DISPLAY DEVICE INCLUDING THE SAME

(71) Applicant: Samsung Display Co., Ltd., Yongin-si (KR)

(72) Inventors: DONGJIN MOON, Yongin-si (KR); JUNSEOK MIN, Yongin-si (KR); KYUNGSU LEE, Yongin-si (KR)

(21) Appl. No.: 18/812,905

(22) Filed: Aug. 22, 2024

(30) Foreign Application Priority Data
Nov. 15, 2023 (KR) 10-2023-0157953

(51) Int. Cl. G06F 3/044; H10K 59/40

(52) U.S. Cl. CPC G06F 3/0446; H10K 59/40; G06F 2203/04111; G06F 2203/04112

(57) ABSTRACT

An input sensor includes: a first-first sensor and a first-second sensor arranged in a first direction with a hole therebetween; two second sensors arranged in a second direction crossing the first direction with the hole therebetween and connected with each other; a first connecting line between each of the first-first and first-second sensors and the hole, the first connecting line connected to the first-first and first-second sensors by extending along the hole; and a connecting part between the first-first sensor and the first connecting line to connect the first-first sensor to the first connecting line, wherein the connecting part includes: a first extension connected to a edge of the first-first sensor by extending along the edge of the first-first sensor; and a second extension connected to the first connecting line by extending from a portion of the first extension toward the first connecting line.

### CROSS-REFERENCE TO RELATED APPLICATION

The present application claims priority to and the benefit of Korean Patent Application No. 10-2023-0157953, filed on Nov. 15, 2023, in the Korean Intellectual Property Office, the entire disclosures of which is incorporated herein by reference.

### BACKGROUND

Aspects of some embodiments of the present disclosure described herein relate to an input sensing part (or input sensor) and a display device including the same.

In general, an electronic device, such as a smart phone, a digital camera, a notebook computer, a car navigation unit, a smart television, or the like, which displays images to a user includes a display device for displaying images. The display device generates images and provides the generated images to the user through a display screen. The display device includes a display panel for generating images, an input device such as an input sensing part, a camera for taking an external image, and various sensors.

The input sensing part (or input sensor) may be located on the display panel and senses a touch of the user as an external input. The input sensing part includes a plurality of sensing parts for sensing an external input by forming capacitance.

A camera and at least one sensor may be located in holes continuously defined in the display panel and the input sensing part. When the holes are defined, sensing parts around the holes may be connected through connecting lines bypassing the holes.

The above information disclosed in this Background section is only for enhancement of understanding of the background and therefore the information discussed in this Background section does not necessarily constitute prior art.

### SUMMARY

Aspects of some embodiments of the present disclosure include an input sensing part (or input sensor) that may be capable of providing a relatively more robust connection between first and second connecting parts and first sensing parts around a hole and relatively reducing the resistance of a second connecting line and a display device including the input sensing part.

According to some embodiments, an input sensing part includes a first-first sensing part and a first-second sensing part arranged in a first direction with a hole therebetween, two second sensing parts arranged in a second direction crossing the first direction with the hole therebetween and connected with each other, a first connecting line between each of the first-first and first-second sensing parts and the hole and connected to the first-first and first-second sensing parts by extending along the hole, and a connecting part between the first-first sensing part and the first connecting line to connect the first-first sensing part to the first connecting line. The connecting part includes a first extension connected to a edge of the first-first sensing part by extending along the edge of the first-first sensing part and a second extension connected to the first connecting line by extending from a portion of the first extension toward the first connecting line.

According to some embodiments, an input sensing part includes a first-first sensing part and a first-second sensing part arranged in a first direction with a hole therebetween, two second sensing parts arranged in a second direction crossing the first direction with the hole therebetween and connected with each other, a first connecting line between each of the first-first and first-second sensing parts and the hole and connected to the first-first and first-second sensing parts by extending along the hole, and a connecting part between the first-first sensing part and the first connecting line to connect the first-first sensing part to the first connecting line, and the connecting part has a shape of “T”.

According to some embodiments, a display device includes a display panel and an input sensing part on the display panel. According to some embodiments, a hole is continuously defined in the display panel and the input sensing part. According to some embodiments, the input sensing part includes a first-first sensing part and a first-second sensing part arranged in a first direction with the hole therebetween, two second sensing parts arranged in a second direction crossing the first direction with the hole therebetween and connected with each other, a first connecting line between each of the first-first and first-second sensing parts and the hole and connected to the first-first and first-second sensing parts by extending along the hole, and a connecting part between the first-first sensing part and the first connecting line to connect the first-first sensing part to the first connecting line. According to some embodiments, the connecting part includes a first extension connected to a edge of the first-first sensing part by extending in the second direction and a second extension connected to the first connecting line by extending from a portion of the first extension in the first direction.

### BRIEF DESCRIPTION OF THE FIGURES

The above and other aspects and features of the present disclosure will become more apparent by describing in more detail aspects of some embodiments thereof with reference to the accompanying drawings.

FIG. 1 is a perspective view of a display device including an input sensing part (or input sensor) according to some embodiments of the present disclosure.

FIG. 2 is a sectional view taken along the line I-I′ illustrated in FIG. 1.

FIG. 3 is a view illustrating a section of a display panel corresponding to the line II-II′ illustrated in FIG. 1.

FIG. 4 is a plan view of the display panel illustrated in FIG. 2.

FIG. 5 is a view illustrating a section of the display panel corresponding to one pixel illustrated in FIG. 4.

FIG. 6 is a plan view of the input sensing part (or input sensor) illustrated in FIG. 2.

FIG. 7 is an enlarged view of a first region AA1 illustrated in FIG. 6.

FIG. 8 is an enlarged view illustrating some of the first sensing parts and some of the second sensing parts illustrated in FIG. 7, where FIG. 8 illustrates a detailed configuration of the first and second sensing parts.

FIG. 9 is an enlarged view illustrating some of the touch openings defined by mesh lines illustrated in FIG. 8.

FIG. 10 is a sectional view taken along the line III-III′ illustrated in FIG. 7.

FIG. 11 is a sectional view taken along the line IV-IV′ illustrated in FIG. 7.

FIG. 12 is an enlarged view of a first hole and a region around the first hole illustrated in FIG. 6.

FIG. 13 is an enlarged view of a second region AA2 illustrated in FIG. 12.

FIG. 14A is a view illustrating first and second connecting lines and a lower electrode of each of first connecting parts illustrated in FIG. 13.

FIG. 14B is a view illustrating the first and second connecting lines and an upper electrode of each of the first connecting parts illustrated in FIG. 13.

FIG. 15 is a sectional view taken along the line V-V′ illustrated in FIG. 13.

FIG. 16 is a sectional view taken along the line VI-VI′ illustrated in FIG. 13.

FIG. 17 is an enlarged view of a third region AA3 illustrated in FIG. 12.

FIG. 18 is an enlarged view of a second hole and a region around the second hole illustrated in FIG. 6.

FIG. 19 is an enlarged view of a fourth region AA4 illustrated in FIG. 18.

FIG. 20 is an enlarged view of a fifth region AA5 illustrated in FIG. 18.

FIG. 21 is a view illustrating a configuration of a first connecting line and a second connecting line around a first hole according to some embodiments of the present disclosure.

FIG. 22 is a view illustrating a configuration of a first connecting line and a second connecting line around a second hole according to some embodiments of the present disclosure.

FIG. 23 is a view illustrating a configuration of a first connecting part and a second connecting line according to some embodiments of the present disclosure.

FIG. 24 is a view illustrating a configuration of a first connecting part according to some embodiments of the present disclosure.

### DETAILED DESCRIPTION

In this specification, when it is mentioned that a component (or, a region, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, aspects of some embodiments of the present disclosure will be described with reference to the accompanying drawings.

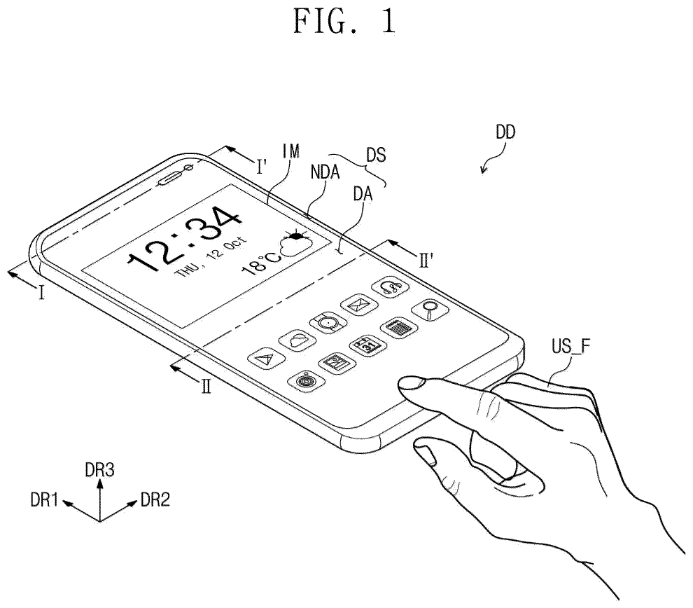

FIG. 1 is a perspective view of a display device including an input sensing part (or input sensor) according to some embodiments of the present disclosure.

Referring to FIG. 1, the display device DD according to some embodiments of the present disclosure may have a quadrangular shape with long sides extending in a first direction DR1 and short sides extending in a second direction DR2 crossing the first direction DR1. However, without being limited thereto, the display device DD may have various shapes such as a circular shape, a polygonal shape, or any other suitable shape in a plan view (e.g., from the direction DR3) according to the design of the display device DD.

Hereinafter, a direction perpendicular (or substantially perpendicular) to a plane defined by the first direction DR1 and the second direction DR2 is defined as a third direction DR3. As used herein, the expressions “when viewed from above the plane” or “in a plan view” may mean that it is viewed from the third direction DR3.

The upper surface of the display device DD may be defined as a display surface DS and may have a plane defined by the first direction DR1 and the second direction DR2. Images IM generated by the display device DD may be provided to a user through the display surface DS. The display device DD may sense a touch of the user's finger US_F on the display device DD.

The display surface DS may include a display region DA and a non-display region NDA around (e.g., in a periphery or outside a footprint of) the display region DA. The display region DA may display images, and the non-display region NDA may not display images. The non-display region NDA may surround the display region DA and may define the border of (or bezel around) the display device DD that is printed in a certain color (e.g., black).

The display device DD may include a camera CM and a sensor SN. The camera CM and the sensor SN may be adjacent to the border of the display device DD. The camera CM and the sensor SN may be located in the display region DA adjacent to the non-display region NDA. The camera CM may be configured to take or capture images of external objects or scenery. The sensor SN may be a proximity illuminance sensor. However, the type of the sensor SN is not limited thereto.

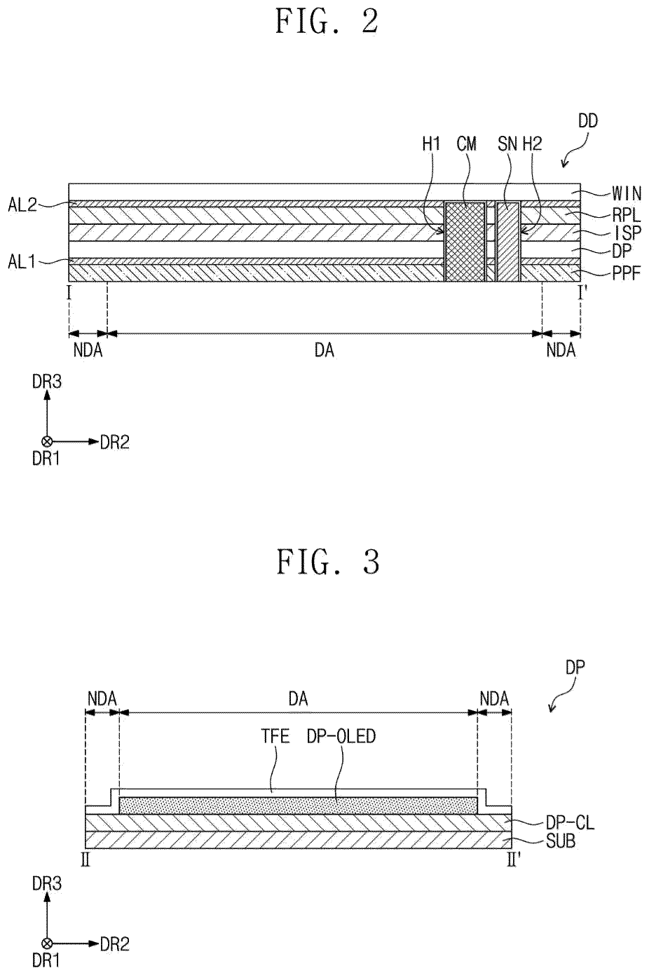

FIG. 2 is a sectional view taken along the line I-I′ illustrated in FIG. 1.

Referring to FIG. 2, the display device DD may include a display panel DP, the input sensing part (or input sensor) ISP, an anti-reflective layer RPL, a window WIN, a panel protection film PPF, and first and second adhesive layers AL1 and AL2.

The display panel DP may be a flexible display panel. The display panel DP according to some embodiments of the present disclosure may be an emissive display panel, but embodiments according to the present disclosure are not particularly limited thereto. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots, quantum rods, and the like. Hereinafter, it will be illustrated and described that the display panel DP is an organic light emitting display panel, but embodiments according to the present disclosure are not limited thereto.

The input sensing part ISP may be located on the display panel DP. The input sensing part ISP may include a plurality of sensing parts for sensing an external input in a capacitive type of sensing manner. The input sensing part ISP may be directly manufactured on the display panel DP when the display device DD is manufactured. However, without being limited thereto, the input sensing part ISP may be manufactured as a panel separate from the display panel DP and may be attached to the display panel DP, for example, by an adhesive layer.

The anti-reflective layer RPL may be located on the input sensing part ISP. The anti-reflective layer RPL may be directly manufactured on the input sensing part ISP when the display device DD is manufactured. However, without being limited thereto, the anti-reflective layer RPL may be manufactured as a separate panel and may be attached to the input sensing part ISP by an adhesive layer.

The anti-reflective layer RPL may be defined as a film for preventing or reducing reflection of external light. The anti-reflective layer RPL may decrease the reflectance of external light incident toward the display panel DP from above the display device DD. Due to the anti-reflective layer RPL, the external light may not be visible to users.

When external light travelling toward the display panel DP is reflected from the display panel DP and provided back to the user, the user may visually recognize the external light (e.g., as in a mirror). To prevent or reduce such a phenomenon, the anti-reflective layer RPL may include a plurality of color filters that display the same colors as those of pixels of the display panel DP, without reflecting or with minimal or reduced reflection of external light.

The color filters may filter the external light into the same colors as those of the pixels. In this case, the external light may not be visible to users. However, without being limited thereto, the anti-reflective layer RPL may include a phase retarder and/or a polarizer to decrease the reflectance of the external light.

The window WIN may be located on the anti-reflective layer RPL. The window WIN may protect the display panel DP, the input sensing part ISP, and the anti-reflective layer RPL from damage due to external scratches and impacts.

The panel protection film PPF may be located under the display panel DP. The panel protection film PPF may protect a lower portion of the display panel DP. The panel protection film PPF may include a flexible plastic material such as polyethylene terephthalate (PET).

The first adhesive layer AL1 may be located between the display panel DP and the panel protection film PPF, and the display panel DP and the panel protection film PPF may be bonded to each other by the first adhesive layer AL1. The second adhesive layer AL2 may be located between the window WIN and the anti-reflective layer RPL, and the window WIN and the anti-reflective layer RPL may be bonded to each other by the second adhesive layer AL2.

A first hole H1 and a second hole H2 may be continuously defined in the anti-reflective layer RPL, the input sensing part ISP, the display panel DP, the panel protection film PPF, and the first and second adhesive layers AL1 and AL2. The first hole H1 may be larger than the second hole H2. For example, the first hole H1 may have a greater width in the second direction DR2 than the second hole H2. The camera CM may be located in the first hole H1, and the sensor SN may be located in the second hole H2.

FIG. 3 is a view illustrating a section of the display panel corresponding to the line II-II′ illustrated in FIG. 1.

Referring to FIG. 3, the display panel DP may include a substrate SUB, a circuit element layer DP-CL located on the substrate SUB, a display element layer DP-OLED located on the circuit element layer DP-CL, and a thin film encapsulation layer TFE located on the display element layer DP-OLED.

The substrate SUB may include a display region DA and a non-display region NDA around (e.g., in a periphery or outside a footprint of) the display region DA. The substrate SUB may include a flexible plastic material such as glass or polyimide (PI). The display element layer DP-OLED may be located on the display region DA.

A plurality of pixels may be located in the circuit element layer DP-CL and the display element layer DP-OLED. Each of the pixels may include transistors located in the circuit element layer DP-CL and a light emitting element located in the display element layer DP-OLED and connected to the transistors.

The thin film encapsulation layer TFE may be located on the circuit element layer DP-CL to cover the display element layer DP-OLED. The thin film encapsulation layer TFE may protect the pixels from moisture, oxygen, and external foreign matter.

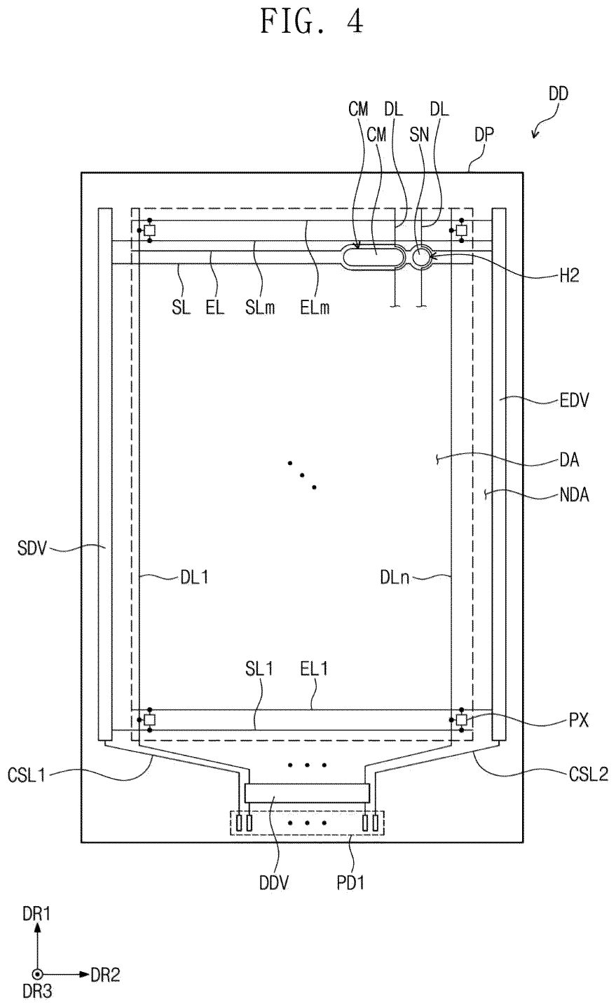

FIG. 4 is a plan view of the display panel illustrated in FIG. 2.

Referring to FIG. 4, the display device DD may include the display panel DP, a scan driver SDV, a data driver DDV, a light emission driver EDV, and a plurality of first pads PD1.

The display panel DP may have a rectangular shape with long sides extending in the first direction DR1 and short sides extending in the second direction DR2. However, the shape of the display panel DP is not limited thereto. The display panel DP may include a display region DA and a non-display region NDA surrounding (e.g., in a periphery or outside a footprint of) the display region DA.

The display panel DP may include a plurality of pixels PX, a plurality of scan lines SL1 to SLm, a plurality of data lines DL1 to DLn, a plurality of light emission lines EL1 to ELm, and first and second control lines CSL1 and CSL2. Here, “m” and “n” are natural numbers.

The pixels PX may be located in the display region DA. The scan driver SDV and the light emission driver EDV may be located in the non-display regions NDA adjacent to the long sides of the display panel DP, respectively. The data driver DDV may be located in the non-display region NDA adjacent to one of the short sides of the display panel DP. The data driver DDV may be adjacent to the lower end of the display panel DP when viewed from above the plane (e.g., in a plan view).

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emission lines EL1 to ELm may extend in the second direction DR2 and may be connected to the pixels PX and the light emission driver EDV.

The first control line CSL1 may be connected to the scan driver SDV and may extend toward the lower end of the display panel DP. The second control line CSL2 may be connected to the light emission driver EDV and may extend toward the lower end of the display panel DP. The data driver DDV may be located between the first control line CSL1 and the second control line CSL2.

The first pads PD1 may be located in the non-display region NDA adjacent to the lower end of the display panel DP and may be closer to the lower end of the display panel DP than the data driver DDV. The data driver DDV, the first control line CSL1, and the second control line CSL2 may be connected to the first pads PD1. The data lines DL1 to DLn may be connected to the data driver DDV, and the data driver DDV may be connected to the first pads PD1 corresponding to the data lines DL1 to DLn.

According to some embodiments, the display device DD may further include a timing controller for controlling operations of the scan driver SDV, the data driver DDV, and the light emission driver EDV and a voltage generator for generating first and second voltages. The timing controller and the voltage generator may be connected to the first pads PD1 through a printed circuit board.

The first voltage and the second voltage may be defined as drive voltages for driving the pixels PX. The first voltage may be applied to an anode of a light emitting element of each of the pixels PX, and the second voltage may be applied to a cathode of the light emitting element of the pixel PX. According to some embodiments, the first voltage may be applied to the pixels PX through a first power line, and the second voltage may be applied to the pixels PX through a second power line.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light emission signals, and the light emission signals may be applied to the pixels PX through the light emission lines EL1 to ELm.

The pixels PX may receive the data voltages in response to the scan signals. The pixels PX may display images by emitting light having luminance corresponding to the data voltages in response to the light emission signals.

The first hole H1 and the second hole H2 may be defined in the display panel DP, and the camera CM and the sensor SN may be located in the first hole H1 and the second hole H2, respectively. Some lines SL, EL, and DL adjacent to the first hole H1 and the second hole H2 may extend to bypass the first hole H1 and the second hole H2. For example, pixels capable of being connected to the some lines SL, EL, and DL adjacent to the first hole H1 and the second hole H2 are omitted in FIG. 4.

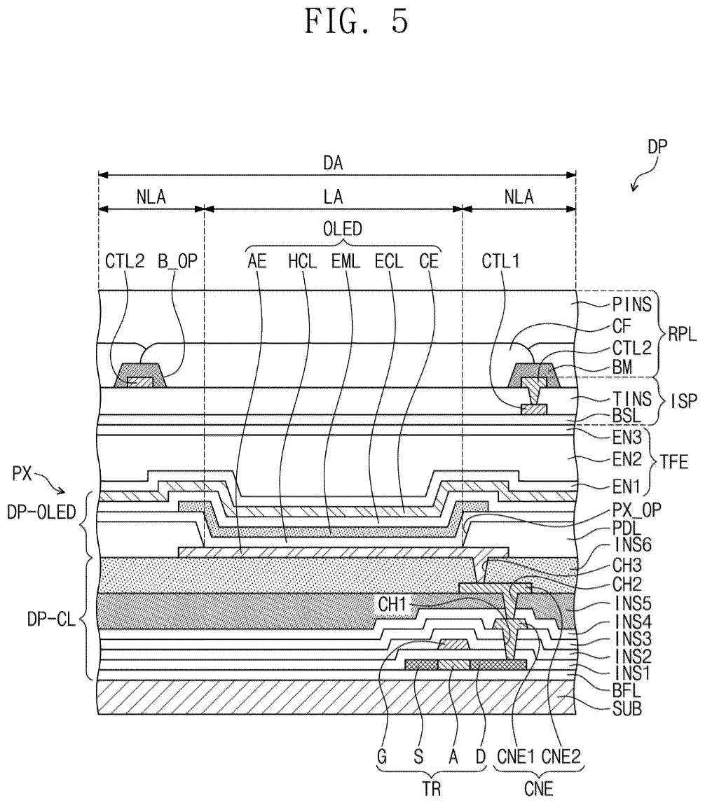

FIG. 5 is a view illustrating a section of the display panel corresponding to one pixel illustrated in FIG. 4.

Referring to FIG. 5, the pixel PX may include a transistor TR and a light emitting element OLED. The light emitting element OLED may include a first electrode AE (or, an anode), a second electrode CE (or, a cathode), a hole control layer HCL, an electron control layer ECL, and an emissive layer EML.

The transistor TR and the light emitting element OLED may be located on the substrate SUB. Although one transistor TR is illustrated as an example, the pixel PX may substantially include a plurality of transistors and at least one capacitor for driving the light emitting element OLED.

The display region DA may include an emissive region LA corresponding to each of the pixels PX and a non-emissive region NLA around the emissive region LA. The light emitting element OLED may be located in the emissive region LA.

A buffer layer BFL may be located on the substrate SUB. The buffer layer BFL may be an inorganic layer. A semiconductor pattern may be located on the buffer layer BFL. The semiconductor pattern may include poly silicon, amorphous silicon, or metal oxide.

The semiconductor pattern may be doped with an N-type dopant or a P-type dopant. The semiconductor pattern may include heavily doped regions and a lightly doped region. The heavily doped regions may have a higher conductivity than the lightly doped region and may serve as a source electrode and a drain electrode of the transistor TR. The lightly doped region may correspond (or substantially correspond) to an active (or, channel) region of the transistor TR.

The source S, the active region A, and the drain D of the transistor TR may be formed from the semiconductor pattern. A first insulating layer INS1 may be located on the semiconductor pattern. A gate G of the transistor TR may be located on the first insulating layer INS1. A second insulating layer INS2 may be located on the gate G. A third insulating layer INS3 may be located on the second insulating layer INS2.

To connect the transistor TR and the light emitting element OLED, a connecting electrode CNE may include a first connecting electrode CNE1 and a second connecting electrode CNE2. The first connecting electrode CNE1 may be located on the third insulating layer INS3 and may be connected to the drain D through a first contact hole CH1 defined in the first to third insulating layers INS1 to INS3.

A fourth insulating layer INS4 may be located on the first connecting electrode CNE1. A fifth insulating layer INS5 may be located on the fourth insulating layer INS4. The second connecting electrode CNE2 may be located on the fifth insulating layer INS5. The second connecting electrode CNE2 may be connected to the first connecting electrode CNE1 through a second contact hole CH2 defined in the fourth and fifth insulating layers INS4 and INS5.

A sixth insulating layer INS6 may be located on the second connecting electrode CNE2. The layers from the buffer layer BFL to the sixth insulating layer INS6 may be defined as the circuit element layer DP-CL. The first to sixth insulating layers INS1 to INS6 may be inorganic layers or organic layers.

The first electrode AE may be located on the sixth insulating layer INS6. The first electrode AE may be connected to the second connecting electrode CNE2 through a third contact hole CH3 defined in the sixth insulating layer INS6. A pixel defining layer PDL having an opening PX_OP defined therein to expose a certain portion of the first electrode AE may be located on the first electrode AE and the sixth insulating layer INS6.

The hole control layer HCL may be located on the first electrode AE and the pixel defining layer PDL. The hole control layer HCL may include a hole transport layer and a hole injection layer.

The emissive layer EML may be located on the hole control layer HCL. The emissive layer EML may be located in a region corresponding to the opening PX_OP. The emissive layer EML may include an organic material and/or an inorganic material. The emissive layer EML may generate one of red light, green light, and blue light.

The electron control layer ECL may be located on the emissive layer EML and the hole control layer HCL. The electron control layer ECL may include an electron transport layer and an electron injection layer. The hole control layer HCL and the electron control layer ECL may be commonly located in the emissive region LA and the non-emissive region NLA.

The second electrode CE may be located on the electron control layer ECL. The second electrode CE may be commonly located in the pixels PX. The layer in which the light emitting element OLED is located may be defined as the display element layer DP-OLED.

The thin film encapsulation layer TFE may be located on the second electrode CE and may cover the pixel PX. The thin film encapsulation layer TFE may include a first encapsulation layer EN1 located on the second electrode CE, a second encapsulation layer EN2 located on the first encapsulation layer EN1, and a third encapsulation layer EN3 located on the second encapsulation layer EN2.

The first and third encapsulation layers EN1 and EN3 may include inorganic insulating layers and may protect the pixel PX from moisture/oxygen. The second encapsulation layer EN2 may include an organic insulating layer and may protect the pixel PX from foreign matter such as dust particles.

The first voltage may be applied to the first electrode AE through the transistor TR, and the second voltage having a lower level than the first voltage may be applied to the second electrode CE. Holes and electrons injected into the emissive layer EML may be combined to form excitons, and as the excitons transition to a ground state, the light emitting element OLED may emit light.

The input sensing part ISP may be located on the thin film encapsulation layer TFE. The input sensing part ISP may be directly manufactured on the upper surface of the thin film encapsulation layer TFE.

A base layer BSL may be located on the thin film encapsulation layer TFE. The base layer BSL may include an inorganic insulating layer. At least one inorganic insulating layer may be provided on the thin film encapsulation layer TFE as the base layer BSL.

The input sensing part ISP may include a first conductive pattern CTL1 and a second conductive pattern CTL2 located on the first conductive pattern CTL1. The first conductive pattern CTL1 may be located on the base layer BSL. An insulating layer TINS may be located on the base layer BSL to cover the first conductive pattern CTL1. The insulating layer TINS may include an inorganic insulating layer or an organic insulating layer. The second conductive pattern CTL2 may be located on the insulating layer TINS.

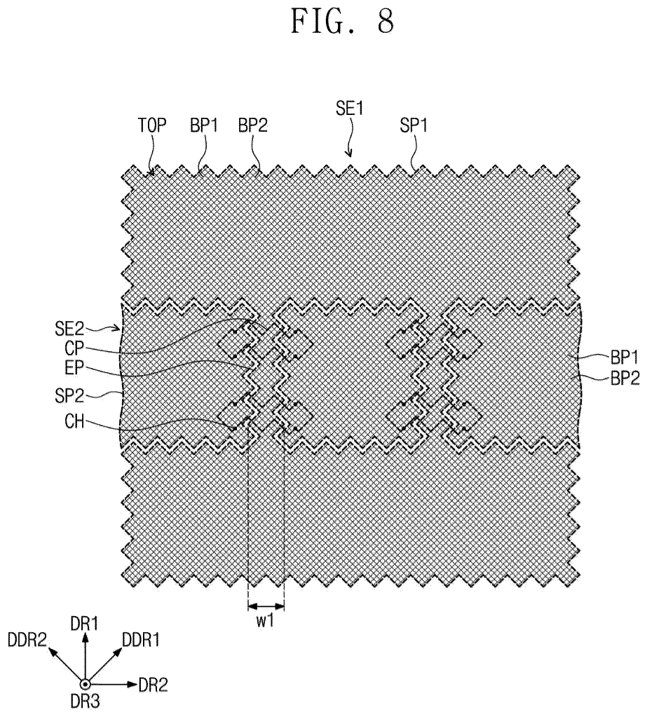

The first and second conductive patterns CTL1 and CTL2 may overlap the non-emissive region NLA. According to some embodiments, the first and second conductive patterns CTL1 and CTL2 may be located on the non-emissive region NLA between the emissive regions LA and may have a mesh shape. This structure will be described below in more detail with reference to FIG. 8.

The first and second conductive patterns CTL1 and CTL2 may form sensors of the input sensing part ISP described above. For example, the first and second conductive patterns CTL1 and CTL2 having a mesh shape may be separated from each other in a certain region to form the sensors. A portion of the second conductive pattern CTL2 may be connected to the first conductive pattern CTL1. The configuration of the sensors formed by the first and second conductive patterns CTL1 and CTL2 will be described below in detail.

The anti-reflective layer RPL may be located on the second conductive pattern CTL2. The anti-reflective layer RPL may include a black matrix BM and a plurality of color filters CF. The black matrix BM may overlap the non-emissive region NLA, and the color filters CF may overlap the emissive regions LA, respectively.

The black matrix BM may be located on the insulating layer TINS to cover the second conductive pattern CTL2. An opening B_OP overlapping the emissive region LA and the opening PX_OP may be defined in the black matrix BM. The black matrix BM may absorb and block light. The width of the opening B_OP may be greater than the width of the opening PX_OP.

The color filters CF may be located on the insulating layer TINS and the black matrix BM. The color filters CF may be located in the openings B_OP, respectively. A planarization insulating layer PINS may be located on the color filters CF. The planarization insulating layer PINS may provide a flat upper surface.

The anti-reflective layer RPL may include the plurality of color filters CF that display the same colors as those of the pixels PX of the display panel DP. The color filters CF may filter external light into the same colors as those of the pixels PX. In this case, the external light may not be visible to the user.

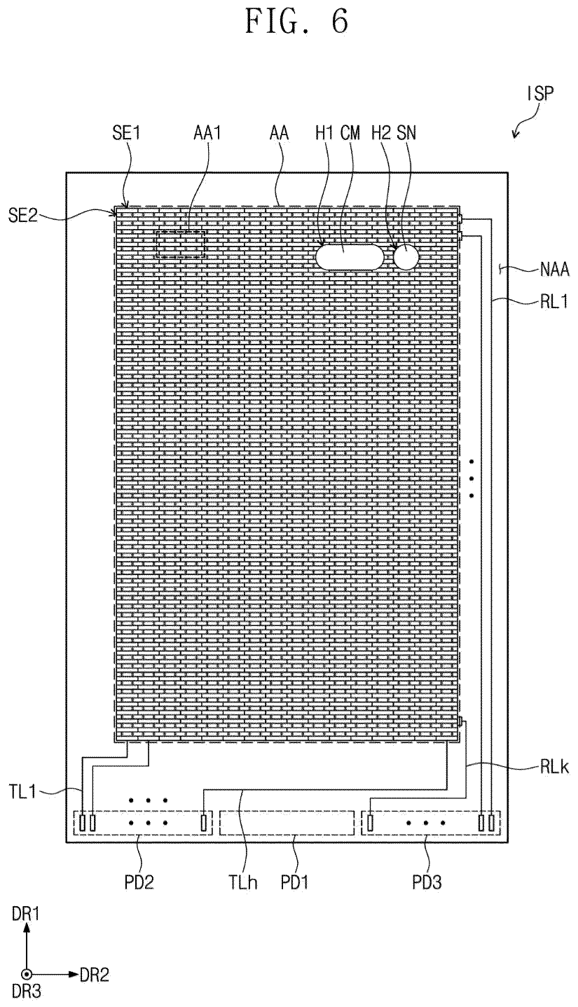

FIG. 6 is a plan view of the input sensing part illustrated in FIG. 2.

Referring to FIG. 6, the input sensing part ISP may include a plurality of sensing electrodes SE1 and SE2, a plurality of lines TL1 to TLh and RL1 to RLk, and a plurality of second and third pads PD2 and PD3. The sensing electrodes SE1 and SE2, the lines TL1 to TLh and RL1 to RLk, and the second and third pads PD2 and PD3 may be located on the thin film encapsulation layer TFE. Here, “h” and “k” are natural numbers.

A planar region of the input sensing part ISP may include an active region AA and an inactive region NAA around (e.g., in a periphery or outside a footprint of) the active region AA. The active region AA may overlap the display region DA, and the inactive region NAA may overlap the non-display region NDA.

The sensing electrodes SE1 and SE2 may be located in the active region AA, and the second and third pads PD2 and PD3 may be located in the inactive region NAA. The second pads PD2 and the third pads PD3 may be adjacent to the lower end of the input sensing part ISP when viewed from above the plane (e.g., in a plan view). The first pads PD1 may be located between the second pads PD2 and the third pads PD3 when viewed from above the plane (e.g., in a plan view).

The lines TL1 to TLh and RL1 to RLk may be connected to ends of the sensing electrodes SE1 and SE2. The lines TL1 to TLh and RL1 to RLk may extend to the inactive region NAA and may be connected to the second and third pads PD2 and PD3. According to some embodiments, a sensing controller for controlling the input sensing part ISP may be connected to the second and third pads PD2 and PD3 through a printed circuit board.

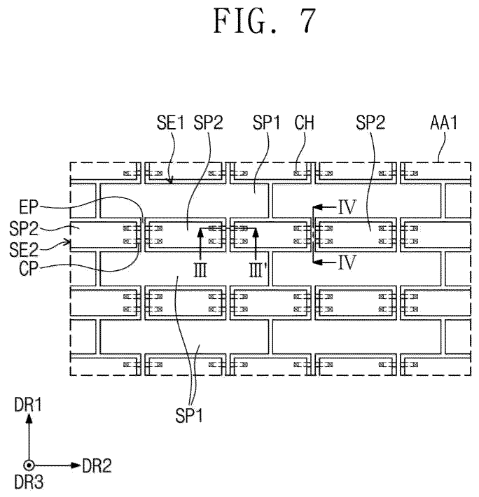

The sensing electrodes SE1 and SE2 may include the plurality of first sensing electrodes SE1 that extend in the first direction DR1 and that are arranged in the second direction DR2 and the plurality of second sensing electrodes SE2 that extend in the second direction DR2 and that are arranged in the first direction DR1. The second sensing electrodes SE2 may extend to cross the first sensing electrodes SE1 while being insulated from the first sensing electrodes SE1. A more specific configuration of the first and second sensing electrodes SE1 and SE2 will be described below in more detail with reference to FIGS. 7 and 8.

The lines TL1 to TLh and RL1 to RLk may include the plurality of first lines TL1 to TLh connected to the first sensing electrodes SE1 and the plurality of second lines RL1 to RLk connected to the second sensing electrodes SE2. The first lines TL1 to TLh may extend to the inactive region NAA and may be connected to the second pads PD2.

The second lines RL1 to RLk may extend to the inactive region NAA and may be connected to the third pads PD3. Each of the second lines RL1 to RLk may be connected to a pair of corresponding second sensing electrodes SE2 among the second sensing electrodes SE2 and may be connected to a corresponding third pad PD3 among the third pads PD3.

The first lines TL1 to TLh may be located in the inactive region NAA adjacent to the lower side of the active region AA when viewed from above the plane (e.g., in a plan view). The second lines RL1 to RLk may be located in the inactive region NAA adjacent to the right side of the active region AA when viewed from above the plane (e.g., in a plan view). The first lines TL1 to TLh may be defined as transmission lines, and the second lines RL1 to RLk may be defined as sensing lines.

FIG. 7 is an enlarged view of a first region AA1 illustrated in FIG. 6.

Referring to FIGS. 6 and 7, each of the first sensing electrodes SE1 may include a plurality of first sensing parts (or first sensors) SP1 arranged in the first direction DR1 and a plurality of extending patterns EP that are located between the first sensing parts SP1 and that extend in the first direction DR1.

Two extending patterns EP may be located between two first sensing parts SP1 adjacent to each other in the first direction DR1. The two extending patterns EP may be arranged in the second direction DR2. The first sensing parts SP1 and the extending patterns EP may be integrally formed with each other.

The second sensing electrodes SE2 may extend in the second direction DR2 to cross the extending patterns EP while being insulated from the extending patterns EP. Each of the second sensing electrodes SE2 may include a plurality of second sensing parts (or second sensors) SP2 arranged in the second direction DR2 and a plurality of connecting patterns CP that are located between the second sensing parts SP2 and that connect the second sensing parts SP2. The connecting patterns CP may extend in the second direction DR2.

Two connecting patterns CP may be located between two second sensing parts SP2 adjacent to each other in the second direction DR2. The two connecting patterns CP located between the two second sensing parts SP2 adjacent to each other may be arranged in the first direction DR1 and may connect the two second sensing parts SP2 adjacent to each other.

The second sensing parts SP2 may be located between the first sensing parts SP1 in the first direction DR1 and may be located between the extending patterns EP in the second direction DR2. The connecting patterns CP may extend to cross the extending patterns EP while being insulated from the extending patterns EP. The connecting patterns CP may be connected to the second sensing parts SP2 through contact holes CH defined in an insulating layer (illustrated in FIG. 10).

The first sensing parts SP1 and the second sensing parts SP2 may be spaced apart from each other without overlapping each other when viewed from above the plane (e.g., in a plan view). Capacitance may be formed by the first sensing parts SP1 and the second sensing parts SP2.

The first sensing parts SP1, the second sensing parts SP2, and the extending patterns EP may be located in the same layer. The connecting patterns CP may be located in a layer different from the layer in which the first sensing parts SP1, the second sensing parts SP2, and the extending patterns EP are located. For example, the connecting patterns CP may be located in a layer below the first sensing parts SP1, the second sensing parts SP2, and the extending patterns EP. For example, portions of the connecting patterns CP located below the second sensing parts SP2 are illustrated by dotted lines in FIG. 7.

FIG. 8 is an enlarged view illustrating some of the first sensing parts and some of the second sensing parts illustrated in FIG. 7, where FIG. 8 illustrates a detailed configuration of the first and second sensing parts.

For example, two first sensing parts SP1 adjacent to each other in the first direction DR1 and three second sensing parts SP2 adjacent to one another in the second direction DR2 are illustrated in FIG. 8. The edges of the first sensing parts SP1, the second sensing parts SP2, the extending patterns EP, and the connecting patterns CP are illustrated by dotted lines.

Referring to FIGS. 7 and 8, the first sensing parts SP1, the second sensing parts SP2, the extending patterns EP, and the connecting patterns CP may have a mesh shape. To have a mesh shape, the first sensing parts SP1, the second sensing parts SP2, the extending patterns EP, and the connecting patterns CP may each include a plurality of first branches BP1 extending in a first diagonal direction DDR1 and a plurality of second branches BP2 extending in a second diagonal direction DDR2.

The first diagonal direction DDR1 may be defined as a direction crossing the first and second directions DR1 and DR2 on the plane defined by the first and second directions DR1 and DR2. The second diagonal direction DDR2 may be defined as a direction crossing the first diagonal direction DDR1 on the plane defined by the first and second directions DR1 and DR2. For example, the first direction DR1 and the second direction DR2 may cross each other at a right angle, and the first diagonal direction DDR1 and the second diagonal direction DDR2 may cross each other at a right angle.

The first branches BP1 and the second branches BP2 of each of the first sensing parts SP1 may cross each other and may be integrally formed with each other. The first branches BP1 and the second branches BP2 of each of the second sensing parts SP2 may cross each other and may be integrally formed with each other.

The first branches BP1 and the second branches BP2 of each of the extending patterns EP may cross each other and may be integrally formed with each other. The first branches BP1 and the second branches BP2 of each of the connecting patterns CP may cross each other and may be integrally formed with each other.

According to the above-described structure, touch openings TOP having a rhombic shape may be defined by the first branches BP1 and the second branches BP2. The first branches BP1 and the second branches BP2 may be defined as mesh lines that form a mesh shape.

The extending patterns EP may be integrally formed with the first sensing parts SP1 and may extend from the first sensing parts SP1. Based on the second direction DR2, each of the extending patterns EP may have a first width W1. The first width W1 may be defined as a distance difference between the leftmost side and the rightmost side of each of the extending patterns EP based on the second direction DR2.

The connecting patterns CP may extend below the second sensing parts SP2 and may be connected to the second sensing parts SP2 through the contact holes CH. Although each of the connecting patterns CP is connected to the second sensing parts SP2 through two contact holes CH in FIG. 7, the connecting pattern CP may be connected to the second sensing parts SP2 through more contact holes CH as illustrated in FIG. 8.

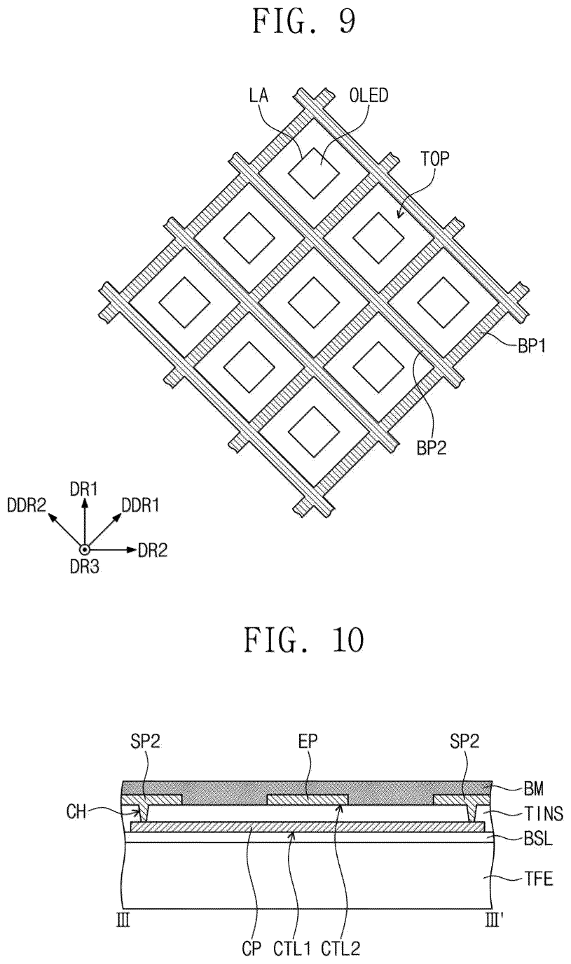

FIG. 9 is an enlarged view illustrating some of the touch openings defined by the mesh lines illustrated in FIG. 8.

Referring to FIGS. 8 and 9, emissive regions LA may be located in the touch openings TOP when viewed from above the plane (e.g., in a plan view). Light emitting elements OLED may be located in the emissive regions LA. Each of the emissive regions LA may correspond to the emissive region LA illustrated in FIG. 5.

Although the emissive regions LA located in some of the touch openings OP are illustrated, emissive regions LA may be located in all of the touch openings TOP illustrated in FIG. 8.

The first and second sensing parts SP1 and SP2, the extending patterns EP, and the connecting patterns CP may be located in the non-emissive region NLA. For example, the first and second branches BP1 and BP2 may be located in the non-emissive region NLA.

Because the first and second sensing parts SP1 and SP2, the extending patterns EP, and the connecting patterns CP are located in the non-emissive region NLA, light generated from the emissive regions LA may be normally output without being affected by the first and second sensing parts SP1 and SP2, the extending patterns EP, and the connecting patterns CP.

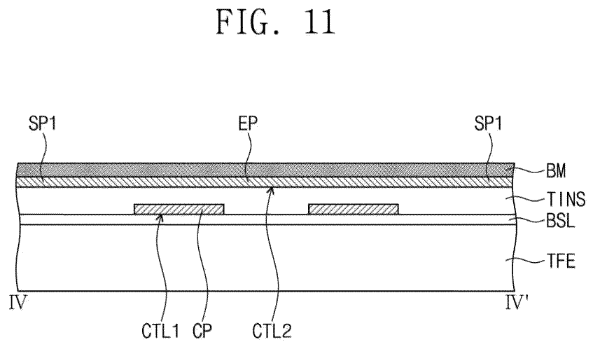

FIG. 10 is a sectional view taken along the line III-III′ illustrated in FIG. 7. FIG. 11 is a sectional view taken along the line IV-IV′ illustrated in FIG. 7.

Line III-III′ and line IV-IV′ illustrated in FIG. 7 may be substantially defined as cutting lines that overlap the mesh lines in FIG. 8 and extend along the mesh lines.

Referring to FIG. 10, the connecting pattern CP may be located on the base layer BSL, and the insulating layer TINS may be located on the connecting pattern CP. The second sensing parts SP2 and the extending pattern EP may be located on the insulating layer TINS. The black matrix BM may be located on the second sensing parts SP2 and the extending pattern EP.

The second sensing parts SP2 may be connected to the connecting pattern CP through the contact holes CH defined in the insulating layer TINS. The extending pattern EP may be located between the second sensing parts SP2.

Referring to FIG. 11, the connecting patterns CP may be located on the base layer BSL, and the insulating layer TINS may be located on the connecting patterns CP. The first sensing parts SP1 and the extending pattern EP may be located on the insulating layer TINS. The first sensing parts SP1 and the extending pattern EP may be integrally formed with each other. The black matrix BM may be located on the first sensing parts SP1 and the extending pattern EP.

Referring to FIGS. 10 and 11, the first and second sensing parts SP1 and SP2 and the extending pattern EP may be located in the same layer. The connecting patterns CP may be located in a layer below the first and second sensing parts SP1 and SP2 and the extending pattern EP. The connecting patterns CP may be formed by the first conductive pattern CTL1 described with reference to FIG. 5. The first and second sensing parts SP1 and SP2 and the extending pattern EP may be formed by the second conductive pattern CTL2 described with reference to FIG. 5.

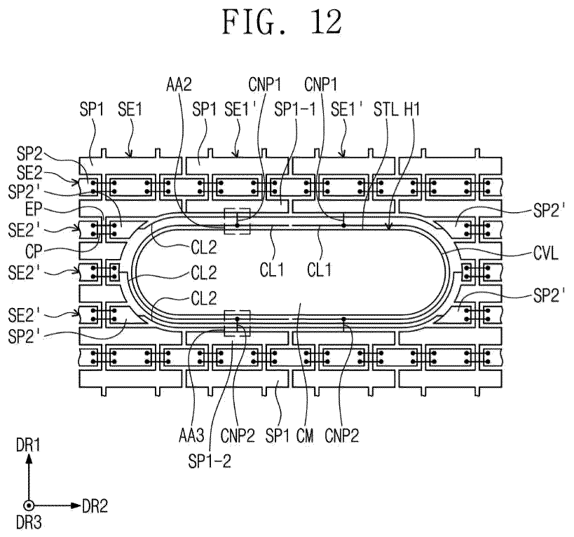

FIG. 12 is an enlarged view of the first hole and the region around the first hole illustrated in FIG. 6.

Referring to FIG. 12, the boundary of the first hole H1 may include straight portions STL extending parallel to each other in the second direction DR2 and curved portions CVL curved outward from opposite ends of the straight portions STL. The curved portions CVL may define opposite sides of the first hole H1 that face away from each other in the second direction DR2. The straight portions STL may define opposite sides of the first hole H1 that face away from each other in the first direction DR1.

Portions of some of the first and second sensing electrodes SE1 and SE2 may be removed to form the first hole H1. Because the first hole H1 is defined in the input sensing part ISP, first and second sensing electrodes SE1′ and SE2′ overlapping the first hole H1 among the first and second sensing electrodes SE1 and SE2 may be separated by the first hole H1. For convenience of description, the first and second sensing electrodes SE1′ and SE2′ separated by the first hole H1 are assigned with separate reference numerals in FIG. 12.

Although it is illustrated that two first sensing electrodes SE1′ and three second sensing electrodes SE2′ are separated by the first hole H1, the numbers of separated first and second sensing electrodes SE1′ and SE2′ may not be limited thereto depending on the size of the first hole H1.

Among the first sensing electrodes SE1, each of the first sensing electrodes SE1′ may be separated by the first hole H1 in the first direction DR1. Among the second sensing electrodes SE2, each of the second sensing electrodes SE2′ may be separated by the first hole H1 in the second direction DR2.

Each of the first sensing electrodes SE1′ may include a first-first sensing part SP1-1 and a first-second sensing part SP1-2 arranged in the first direction DR1 with the first hole H1 therebetween. Each of the second sensing electrodes SE2′ may include two second sensing parts SP2′ arranged in the second direction DR2 with the first hole H1 therebetween. The first-first sensing part SP1-1, the first-second sensing part SP1-2, and the second sensing parts SP2′ may be defined as sensing parts located adjacent to the first hole H1 and separated from one another by the first hole H1.

First sensing parts SP1 of each of the first sensing electrodes SE1′ may be arranged in the first direction DR1 with the first-first sensing part SP1-1 and the first-second sensing part SP1-2. An extending pattern EP may be located between the first-first sensing part SP1-1 and the first sensing part SP1 adjacent to the first-first sensing part SP1-1. An extending pattern EP may be located between the first-second sensing part SP1-2 and the first sensing part SP1 adjacent to the first-second sensing part SP1-2.

The extending pattern EP located between the first-first sensing part SP1-1 and the first sensing part SP1 as described above may extend from the first-first sensing part SP1-1 and the first sensing part SP1. In addition, the extending pattern EP located between the first-second sensing part SP1-2 and the first sensing part SP1 may extend from the first-second sensing part SP1-2 and the first sensing part SP1.

The input sensing part ISP may include a plurality of first connecting lines CL1 for connecting the separated first sensing electrodes SE1′. In addition, the input sensing part ISP may include a plurality of second connecting lines CL2 for connecting the separated second sensing electrodes SE2′.

The first connecting lines CL1 and the second connecting lines CL2 may be arranged around the first hole H1. The first connecting lines CL1 and the second connecting lines CL2 may extend to bypass the first hole H1. The first connecting lines CL1 and the second connecting lines CL2 may extend along the edge of the first hole H1. The first connecting lines CL1 may extend so as not to overlap each other. The second connecting lines CL2 may extend so as not to overlap each other.

Each of the first connecting lines CL1 may connect the first-first sensing part SP1-1 and the first-second sensing part SP1-2 of the corresponding first sensing electrode SE1′ among the first sensing electrodes SE1′. The first connecting line CL1 may be located between the first hole H1 and the first-first and first-second sensing parts SP1-1 and SP1-2 of the corresponding first sensing electrodes SE1′. The first connecting line CL1 may extend along the first hole H1 and may be connected to the first-first and first-second sensing parts SP1-1 and SP1-2 of the corresponding first sensing electrodes SE1′.

Each of the second connecting lines CL2 may connect two second sensing parts SP2′ of the corresponding second sensing electrode SE2′ among the second sensing electrodes SE2′. The second connecting line CL2 may be located between the first hole H1 and the two second sensing parts SP2′ of the corresponding second sensing electrode SE2′. The second connecting line CL2 may extend along the first hole H1 and may be connected to the two second sensing parts SP2′ of the corresponding second sensing electrode SE2′.

The first connecting lines CL1 may extend toward different sides, respectively. For example, the first connecting line CL1 connected to the left first sensing electrodes SE1′ among the first sensing electrodes SE1′ may extend along the left curved portion CVL. The first connecting line CL1 connected to the right first sensing electrodes SE1′ among the first sensing electrodes SE1′ may extend along the right curved portion CVL. However, without being limited thereto, the first connecting lines CL1 may extend toward the same side.

The second connecting lines CL2 may extend toward different sides or the same side. For example, the second connecting line CL2 connected to the second connecting electrode SE2′ adjacent to the upper side of the first hole H1 among the second sensing electrodes SE2′may extend along the upper straight portion STL of the first hole H1.

The second connecting line CL2 connected to the second connecting electrode SE2′ adjacent to the lower side of the first hole H1 among the second sensing electrodes SE2′may extend along the lower straight portion STL of the first hole H1. The second connecting line CL2 connected to the second connecting electrode SE2′ adjacent to the center of the curved portions CVL of the first hole H1 among the second sensing electrodes SE2′may extend along the lower straight portion STL of the first hole H1.

The input sensing part ISP may include a plurality of first connecting parts CNP1 and a plurality of second connecting parts CNP2 for connecting the first connecting lines CL1 to the first sensing electrodes SE1′. A pair of first and second connecting parts CNP1 and CNP2 may connect the corresponding first connecting line CL1 among the first connecting lines CL1 to the first-first and first-second sensing parts SP1-1 and SP1-2 of the corresponding first sensing electrode SE1′ among the first sensing electrodes SE1′.

Each of the first connecting parts CNP1 may be located between the corresponding first-first sensing part SP1-1 and the corresponding first connecting line CL1 and may connect the corresponding first-first sensing part SP1-1 to the corresponding first connecting line CL1.

Each of the second connecting parts CNP2 may be located between the corresponding first-second sensing part SP1-2 and the corresponding first connecting line CL1 and may connect the corresponding first-second sensing part SP1-2 to the corresponding first connecting line CL1.

The second connecting lines CL2 may extend along the first hole H1 so as to be closer to the first-first and first-second sensing parts SP1-1 and SP1-2 than the first connecting lines CL1. Accordingly, the second connecting lines CL2 may extend to cross the first and second connecting parts CNP1 and CNP2.

The second connecting line CL2 connected to the second connecting electrode SE2′ adjacent to the upper side of the first hole H1 may extend to cross the first connecting parts CNP1 while being insulated from the first connecting parts CNP1. The second connecting line CL2 connected to the second connecting electrode SE2′ adjacent to the lower side of the first hole H1 and the second connecting line CL2 connected to the second connecting electrode SE2′ adjacent to the center of the curved portions CVL may extend to cross the second connecting parts CNP2 while being insulated from the second connecting parts CNP2.

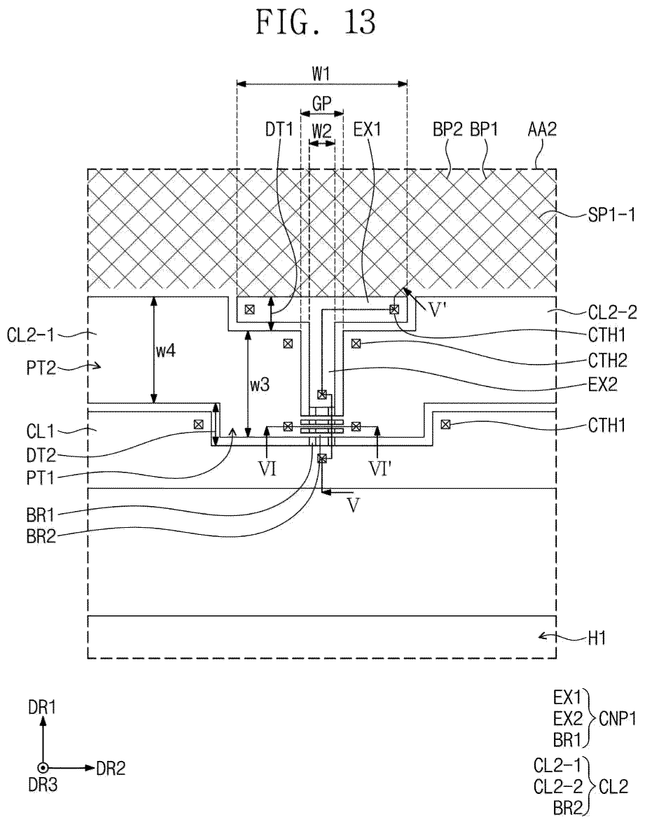

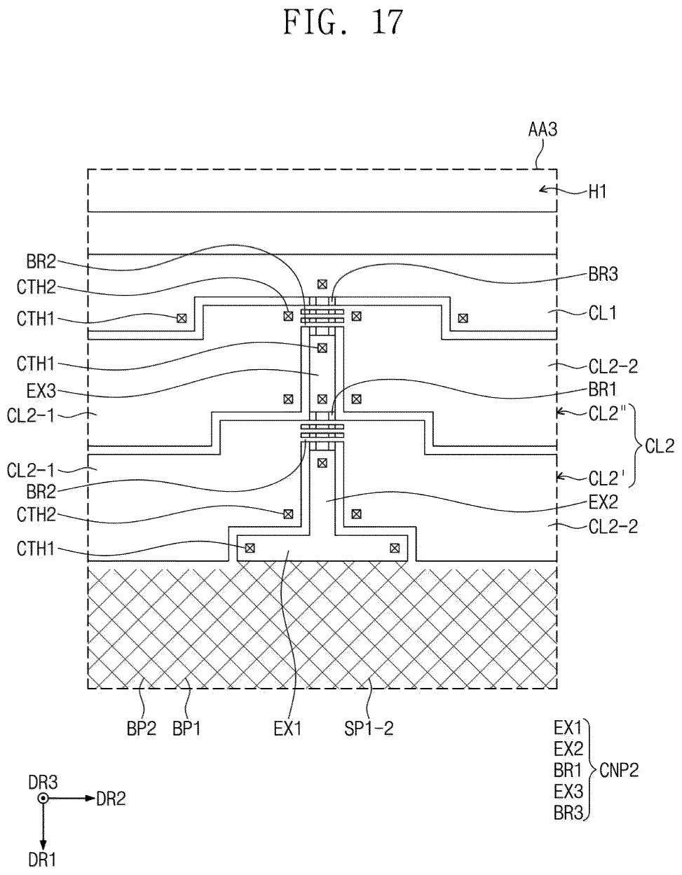

The first connecting parts CNP1 may have the same configuration, and the second connecting parts CNP2 may have the same configuration. Therefore, the configuration of one first connecting part CNP1 and the configuration of one second connecting part CNP2 will be described below with reference to FIGS. 13 and 17.

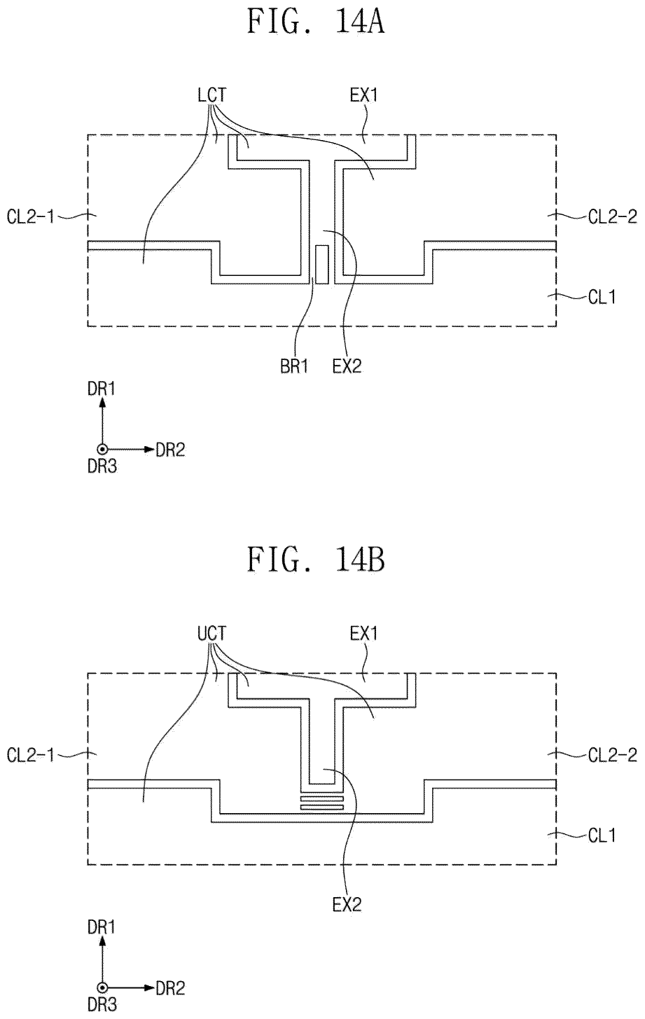

FIG. 13 is an enlarged view of a second region AA2 illustrated in FIG. 12. FIG. 14A is a view illustrating the first and second connecting lines and a lower electrode of each of the first connecting parts illustrated in FIG. 13. FIG. 14B is a view illustrating the first and second connecting lines and an upper electrode of each of the first connecting parts illustrated in FIG. 13.

Referring to FIG. 13, the first connecting part CNP1 may have the shape of “T”. The first connecting part CNP1 may include a first extension EX1, a second extension EX2, and a plurality of first bridge lines BR1.

The first extension EX1 may extend along the edge of the first-first sensing part SP1-1 and may be connected to the first-first sensing part SP1-1. The first extension EX1 and the edge of the first-first sensing part SP1-1 may extend in the second direction DR2. In FIG. 13, the extension direction of the first extension EX1 may be the second direction DR2.

Hereinafter, first and second branches BP1 and BP2 of the first-first sensing part SP1-1 are defined as mesh lines. The first extension EX1 may be connected to five to twenty mesh lines BP1 and BP2, preferably, ten to twenty mesh lines BP1 and BP2.

The second extension EX2 may extend from a portion of the first extension EX1 in the first direction DR1. Based on the second direction DR2 (e.g., the extension direction of the first extension EX1), the first width W1 of the first extension EX1 may be greater than the second width W2 of the second extension EX2. The first width W1 of the first extension EX1 may be equal to the first width W1 of each of the above-described extending patterns EP.

The second extension EX2 may extend toward the first connecting line CL1 and may be connected to the first connecting line CL1. For example, the second extension EX2 may be connected to the first connecting line CL1 through the first bridge lines BR1.

The first bridge lines BR1 may extend in the first direction DR1 and may be arranged in the second direction DR2. Although two first bridge lines BR1 are illustrated as an example, the number of first bridge lines BR1 is not limited thereto. The first bridge lines BR1 may be located between the second extension EX2 and the first connecting line CL1 and may connect the second extension EX2 and the first connecting line CL1.

The first connecting line CL1 may extend in the second direction DR2. The first connecting line CL1 may extend to opposite sides with respect to the second extension EX2. The first connecting line CL1 adjacent to the second extension EX2 may have a symmetrical shape with respect to the second extension EX2.

The first connecting part CNP1 may be located between the first connecting line CL1 and the first-first sensing part SP1-1. The second connecting line CL2 may extend in the second direction DR2 and may be located between the first connecting line CL1 and the first-first sensing part SP1-1.

The second connecting line CL2 may extend to cross the first connecting part CNP1 while being insulated from the first connecting part CNP1. For example, the second connecting line CL2 may extend to cross the first bridge lines BR1 of the first connecting part CNP1 while being insulated from the first bridge lines BR1 of the first connecting part CNP1.

The second connecting line CL2 may include a second-first connecting CL2-1, a second-second connecting line CL2-2, and a plurality of second bridge lines BR2. The second-first connecting CL2-1 and the second-second connecting line CL2-2 may be arranged in the second direction DR2 with the first connecting part CNP1 therebetween. The first and second extensions EX1 and EX2 may be located between the first-first sensing part SP1-1 and the second bridge lines BR2.

The second bridge lines BR2 may extend in the second direction DR2 and may be arranged in the first direction DR1. The second bridge lines BR2 may be located between the second-first connecting CL2-1 and the second-second connecting line CL2-2 and may be connected to the second-first connecting CL2-1 and the second-second connecting line CL2-2.

The second bridge lines BR2 may extend to cross the first bridge lines BR1 while being insulated from the first bridge lines BR1. For example, the second bridge lines BR2 may be located in a layer above the first bridge lines BR1. Although three second bridge lines BR2 are illustrated as an example, the number of second bridge lines BR2 is not limited thereto.

Referring to FIGS. 13, 14A, and 14B, except for the first bridge lines BR1, the first connecting line CL1 and the first and second extensions EX1 and EX2 may have a multi-layer structure. For example, each of the first connecting line CL1 and the first and second extensions EX1 and EX2 may include a lower electrode LCT and an upper electrode UCT located on the lower electrode LCT.

When viewed from above the plane (e.g., in a plan view), the lower electrode LCT and the upper electrode UCT of each of the first connecting line CL1 and the first and second extensions EX1 and EX2 except for the first bridge lines BR1 may have substantially the same shape and may be arranged to overlap each other.

The upper electrodes UCT of the first connecting line CL1 and the first and second extensions EX1 and EX2 may be connected to the lower electrodes LCT of the first connecting line CL1 and the first and second extensions EX1 and EX2 through first contact holes CTH1 defined to overlap the upper electrodes UCT of the first connecting line CL1 and the first and second extensions EX1 and EX2.

The first bridge lines BR1 may extend from the lower electrode LCT of the second extension EX2 and the lower electrode LCT of the first connecting line CL1. The lower electrodes LCT of the first connecting line CL1 and the first and second extensions EX1 and EX2 may be integrally formed with the first bridge lines BR1. The lower electrodes LCT of the first connecting line CL1 and the first and second extensions EX1 and EX2 and the first bridge lines BR1 may be defined as the above-described first conductive pattern CTL1.

The upper electrode UCT of the first connecting line CL1 and the upper electrodes UCT of the first and second extensions EX1 and EX2 may be separated. The upper electrodes UCT of the first connecting line CL1 and the first and second extensions EX1 and EX2 may be defined as the above-described second conductive pattern CTL2.

Except for the second bridge lines BR2, each of the second-first and second-second connecting lines CL2-1 and CL2-2 may have a multi-layer structure. For example, each of the second-first and second-second connecting lines CL2-1 and CL2-2 may include a lower electrode LCT and an upper electrode UCT located on the lower electrode LCT.

When viewed from above the plane (e.g., in a plan view), the lower electrode LCT and the upper electrode UCT of each of the second-first and second-second connecting lines CL2-1 and CL2-2 except for the second bridge lines BR2 may have substantially the same shape and may be arranged to overlap each other.

The upper electrodes UCT of the second-first and second-second connecting lines CL2-1 and CL2-2 may be connected to the lower electrodes LCT of the second-first and second-second connecting lines CL2-1 and CL2-2 through second contact holes CTH2 defined to overlap the upper electrodes UCT of the second-first and second-second connecting lines CL2-1 and CL2-2.

The second bridge lines BR2 may extend from the upper electrode UCT of the second-first connecting line CL2-1 and the upper electrode UCT of the second-second connecting line CL2-2. The upper electrodes UCT of the second-first and second-second connecting lines CL2-1 and CL2-2 may be integrally formed with the second bridge lines BR2. The upper electrodes UCT of the second-first and second-second connecting lines CL2-1 and CL2-2 and the second bridge lines BR2 may be defined as the above-described second conductive pattern CTL2.

The lower electrode LCT of the second-first connecting line CL2-1 and the lower electrode LCT of the second-second connecting line CL2-2 may be separated. The lower electrodes LCT of the second-first and second-second connecting lines CL2-1 and CL2-2 may be defined as the above-described first conductive pattern CTL1.

Referring to FIG. 13, based on the second direction DR2, the gap GP between the second-first connecting line CL2-1 and the second-second connecting line CL2-2 may range from 60 micrometers (μm) to 100 micrometers (μm).

The second-first connecting line CL2-1 and the second-second connecting line CL2-2, which are adjacent to the first connecting part CNP1, may have shapes symmetrical to each other with respect to the first connecting part CNP1. Accordingly, the structure of the second-first connecting line CL2-1 will be described below in detail, and description of the structure of the second-second connecting line CL2-2 symmetrical to the second-first connecting line CL2-1 will be omitted.

The second-first connecting line CL2-1 adjacent to the first connecting part CNP1 may include a first portion PT1 and a second portion PT2 formed with a step with respect to the first portion PT1. The first portion PT1 may be located between the first extension EX1 and the first connecting line CL1. The second portion PT2 may be located between the first connecting line CL1 and the edge of the first-first sensing part SP1-1 that is not connected to the first extension EX1.

One side of the first connecting line CL1 that faces the first and second portions PT1 and PT2 may have a step shape corresponding to the step shape defined by the first and second portions PT1 and PT2. An opposite side of the first connecting line CL1 that faces away from the one side of the first connecting line CL1 may have a straight-line shape extending in the second direction DR2. Based on the first direction DR1, the third width W3 of the first portion PT1 and the fourth width W4 of the second portion PT2 may be equal to each other.

Based on the first direction DR1, the distance between one side of the first extension EX1 that is connected to the edge of the first-first sensing part SP1-1 and one side of the first portion PT1 that faces the first extension EX1 may be defined as a first distance DT1. The distance between one side of the first connecting line CL1 that faces the first portion PT1 and one side of the second portion PT2 that faces the first connecting line CL1 may be defined as a second distance DT2. The first distance DT1 and the second distance DT2 may be equal to each other.

Because the plurality of mesh lines are connected to the first extension EX1 extending longer in the second direction DR2, the first connecting part CNP1 and the first-first sensing part SP1-1 may be more robustly connected.

Because the second-first connecting line CL2-1 and the second-second connecting line CL2-2 are located adjacent to each other with the second extension EX2 having a smaller width therebetween, the gap between the second-first connecting line CL2-1 and the second-second connecting line CL2-2 may be reduced. Accordingly, the lengths of the second bridge lines BR2 in the second direction DR2 may be decreased. Resistance may be proportional to length and inversely proportional to area. Because the lengths of the second bridge lines BR2 are decreased, the resistance of the second connecting line CL2 may be decreased.

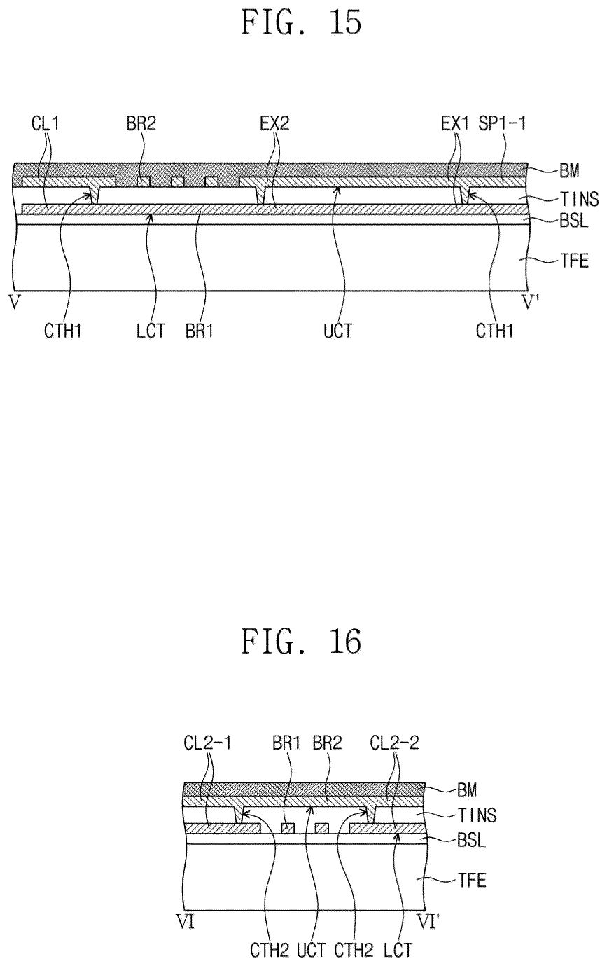

FIG. 15 is a sectional view taken along the line V-V′ illustrated in FIG. 13. FIG. 16 is a sectional view taken along the line VI-VI′ illustrated in FIG. 13.

Referring to FIG. 15, the lower electrodes LCT of the first and second extensions EX1 and EX2, the lower electrode LCT of the first connecting line CL1, and the first bridge line BR1 may be located on the base layer BSL. The insulating layer TINS may be located on the lower electrodes LCT and the first bridge line BR1.

The upper electrodes UCT of the first and second extensions EX1 and EX2, the upper electrode UCT of the first connecting line CL1, and the second bridge lines BR2 may be located on the insulating layer TINS. The lower and upper electrodes LCT and UCT of the first extension EX1, the second extension EX2, and the first connecting line CL1 may be connected by the first contact holes CTH1 defined in the insulating layer TINS.

The first-first sensing part SP1-1 may be located on the insulating layer TINS. The first-first sensing part SP1-1 may be integrally formed with the upper electrode UCT of the first extension EX1. The black matrix BM may be located on the upper electrodes UCT, the first-first sensing part SP1-1, and the second bridge lines BR2.

Referring to FIG. 16, the lower electrodes LCT of the second-first and second-second connecting lines CL2-1 and CL2-2 and the first bridge lines BR1 may be located on the base layer BSL. The insulating layer TINS may be located on the lower electrodes LCT and the first bridge lines BR1.

The upper electrodes UCT of the second-first and second-second connecting lines CL2-1 and CL2-2 and the second bridge line BR2 may be located on the insulating layer TINS. The lower electrodes LCT and the upper electrodes UCT of the second-first and second-second connecting lines CL2-1 and CL2-2 may be connected by the second contact holes CTH2 defined in the insulating layer TINS.

The black matrix BM may be located on the upper electrodes UCT of the second-first and second-second connecting lines CL2-1 and CL2-2 and the second bridge line BR2.

Referring to FIGS. 15 and 16, the first bridge lines BR1 and the second bridge lines BR2 may be insulated from each other by the insulating layer TINS. Accordingly, the second bridge lines BR2 may extend to cross the first bridge lines BR1 while being insulated from the first bridge lines BR1.

FIG. 17 is an enlarged view of a third region AA3 illustrated in FIG. 12.

The connecting structure of the second connecting part CNP2 and the first connecting line CL1 and the structure in which the second connecting lines CL2 cross the second connecting part CNP2 may be substantially similar to the connecting structure of the first connecting part CNP1 and the first connecting line CL1 and the structure in which the second connecting line CL2 crosses the first connecting part CNP1, which are illustrated in FIG. 13. Therefore, the following description will be focused on the difference between the components illustrated in FIG. 17 and the components illustrated in FIG. 13.

Referring to FIG. 17, the second connecting part CNP2 may have the shape of “T”. The second connecting part CNP2 may have a T-shape that is substantially symmetrical to the first connecting part CNP1 in the first direction DR1.

Two second connecting lines CL2 may extend parallel to each other in the second direction DR2 and may extend to cross the second connecting part CNP2 while being insulated from the second connecting part CNP2. The second connecting lines CL2 may be located between the first connecting line CL1 and the second connecting part CNP2 and between the first connecting line CL1 and the first-second sensing part SP1-2.

The second connecting lines CL2 may include a second connecting line CL2′ adjacent to the second connecting part CNP2 and a second connecting line CL2″ adjacent to the first connecting line CL1. The second connecting line CL2″ may be located between the second connecting line CL2′ and the first connecting line CL1.

The first connecting line CL1 illustrated in FIG. 17 may have substantially the same configuration as the first connecting line CL1 illustrated in FIG. 13 and may have a shape symmetrical to the shape of the first connecting line CL1 of FIG. 13 in the first direction DR1. In addition, each of the second connecting lines CL2′ and CL2″ may also have substantially the same configuration as the second connecting line CL2 illustrated in FIG. 13 and may have a shape symmetrical to the shape of the second connecting line CL2 of FIG. 13 in the first direction DR1.

The second connecting part CNP2 may include a first extension EX1, a second extension EX2, a third extension EX3, first bridge lines BR1, and third bridge lines BR3. Each of the second connecting lines CL2′ and CL2″ may include a second-first connecting CL2-1, a second-second connecting line CL2-2, and second bridge lines BR2.

The configuration of the first and second extensions EX1 and EX2, the first bridge lines BR1, and the second connecting line CL2′ may be substantially the same as the configuration of the first and second extensions EX1 and EX2, the first bridge lines BR1, and the second connecting line CL2 illustrated in FIG. 13.

The third extension EX3 may be spaced apart from the second extension EX2 in the first direction DR1. The third extension EX3 may be located between the second bridge lines BR2 of the second connecting line CL2′ and the second bridge lines BR2 of the second connecting line CL2″.

The first bridge lines BR1 may be located between the second extension EX2 and the third extension EX3 and may be connected to the second extension EX2 and the third extension EX3. The third bridge lines BR3 may be located between the third extension EX3 and the first connecting line CL1 and may be connected the third extension EX3 and the first connecting line CL1. The second bridge lines BR2 of the second connecting line CL2″ may extend to cross the third bridge lines BR3 while being insulated from the third bridge lines BR3.

According to some embodiments, except for the first to third bridge lines BR1, BR2, and BR3, each of the first connecting line CL1, the first to third extensions EX1, EX2, and EX3, and the second-first and second-second connecting lines CL2-1 and CL2-2 may have a multi-layer structure including a lower electrode LCT and an upper electrode UCT connected through contact holes CTH1 and CTH2 as illustrated in FIGS. 14A and 14B. Accordingly, the second and third bridge lines BR2 and BR3 may extend from the lower electrode LCT of the third extension EX3. In addition, the third bridge lines BR3 may extend from the lower electrode LCT of the first connecting line CL1.

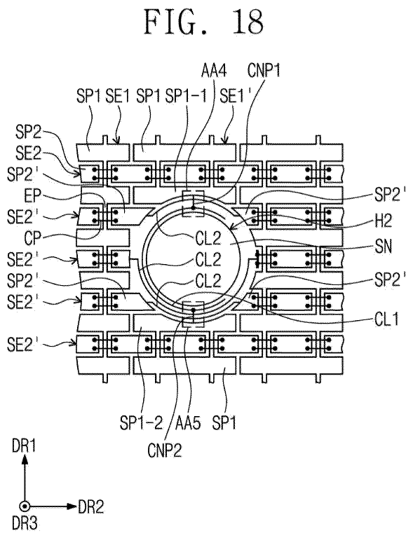

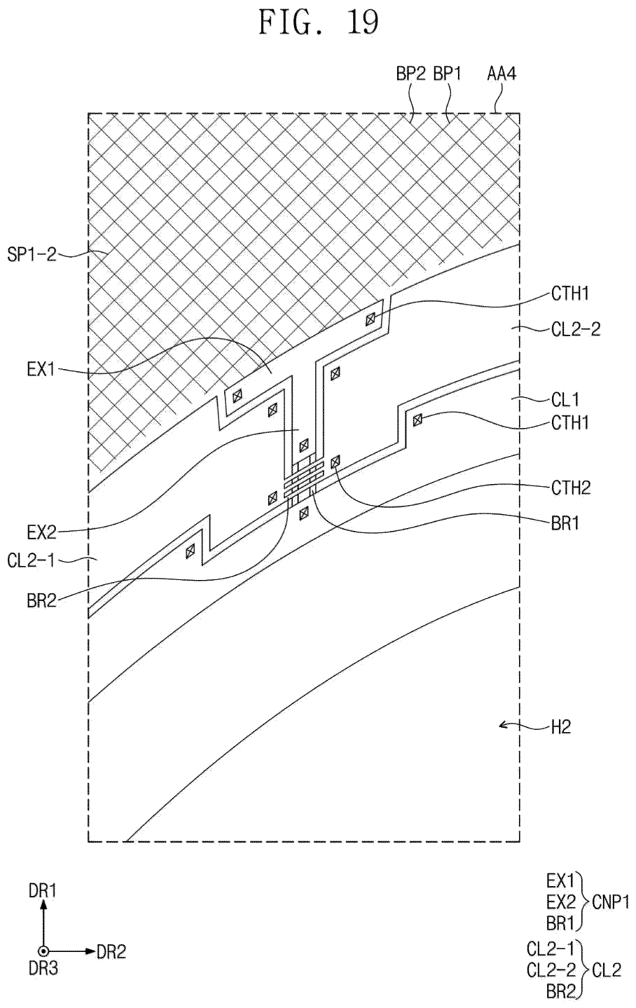

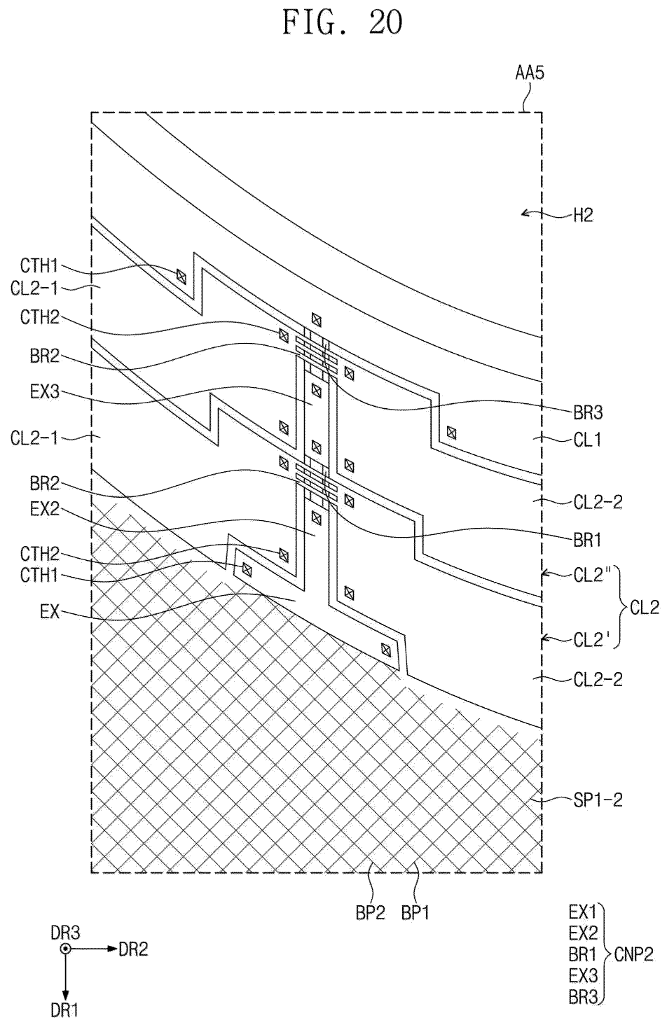

FIG. 18 is an enlarged view of the second hole and the region around the second hole illustrated in FIG. 6. FIG. 19 is an enlarged view of a fourth region AA4 illustrated in FIG. 18. FIG. 20 is an enlarged view of a fifth region AA5 illustrated in FIG. 18.

Depending on the shape of the second hole H2, only the number of separated first sensing electrodes SE1′ differs from that in FIG. 13, and the connection configuration of separated sensing electrodes SE1′ and SE2′ may be substantially the same as the configuration illustrated in FIG. 13. Therefore, the following description will be focused on the difference between the components illustrated in FIG. 18 and the components illustrated in FIG. 13, and components having the same functions are assigned with the same reference numerals.

Referring to FIG. 18, the second hole H2 may have a circular shape. Although the width of the second hole H2 in the first direction DR1 is equal to the width of the first hole H1 in the first direction DR1 as described above, the width of the second hole H2 in the second direction DR2 may be smaller than the width of the first hole H1 in the second direction DR2.

In this case, the number of first sensing electrodes SE1′ separated by the second hole H2 may be smaller than the number of first sensing electrodes SE1′ separated by the first hole H1. For example, one first sensing electrode SE1′ may be separated by the second hole H2. The number of second sensing electrodes SE2′ separated by the second hole H2 may be equal to the number of second sensing electrodes SE2′ separated by the first hole H1.

A first connecting line CL1 may extend along the second hole H2 and may be connected to a first-first sensing part SP1-1 and a first-second sensing part SP1-2 of the first sensing electrodes SE1′. For example, the first connecting line CL1 may extend along the left side of the second hole H2. However, without being limited thereto, the first connecting line CL1 may extend along the right side of the second hole H2.

A first connecting part CNP1 may be located between the first-first sensing part SP1-1 and the first connecting line CL1 and may connect the first-first sensing part SP1-1 to the first connecting line CL1. A second connecting part CNP2 may be located between the first-second sensing part SP1-2 and the first connecting line CL1 and may connect the first-second sensing part SP1-2 to the first connecting line CL1.

Each of second connecting lines CL2 may connect two second sensing parts SP2′ of the corresponding second sensing electrode SE2′ among the second sensing electrodes SE2′. A second connecting line CL2 extending along the upper side of the second hole H2 may extend to cross the first connecting part CNP1 while being insulated from the first connecting part CNP1. Two second connecting lines CL2 extending along the lower side of the second hole H2 may extend to cross the second connecting part CNP2 while being insulated from the second connecting part CNP2.

Referring to FIG. 19, the configuration of the first connecting part CNP1, the first connecting line CL1, and the second connecting line CL2 may be substantially the same as the configuration of the first connecting part CNP1, the first connecting line CL1, and the second connecting line CL2 illustrated in FIG. 13. However, depending on the shape of the second hole H2, the first extension EX1, the first connecting line CL1, and the second connecting line CL2 may extend in a curved direction with respect to the second direction DR2.

Referring to FIG. 20, the configuration of the second connecting part CNP2, the first connecting line CL1, and the second connecting lines CL2′ and CL2″ may be substantially the same as the configuration of the second connecting part CNP2, the first connecting line CL1, and the second connecting line CL2′ and CL2″ illustrated in FIG. 17. However, depending on the shape of the second hole H2, the first extension EX1, the first connecting line CL1, and the second connecting lines CL2′ and CL2″ may extend in a curved direction with respect to the second direction DR2.

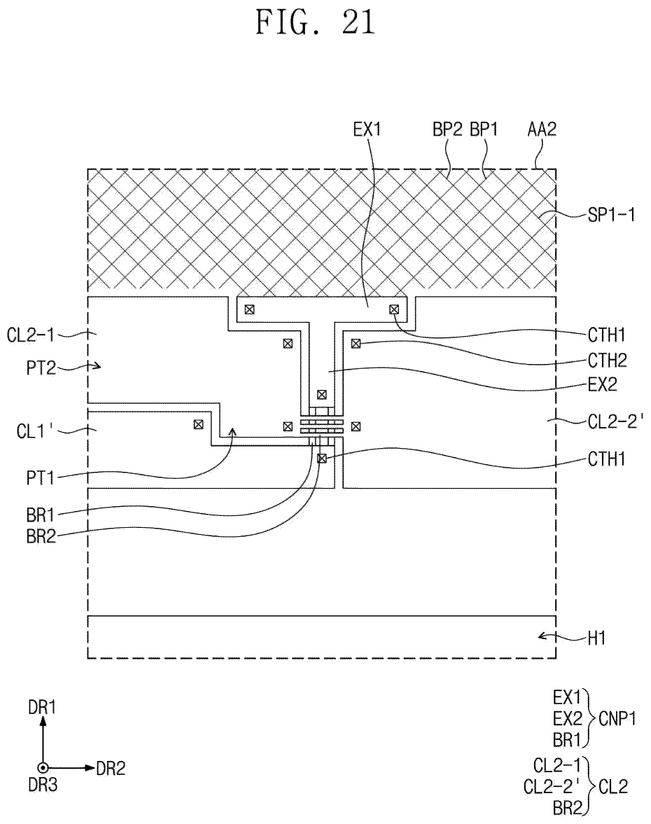

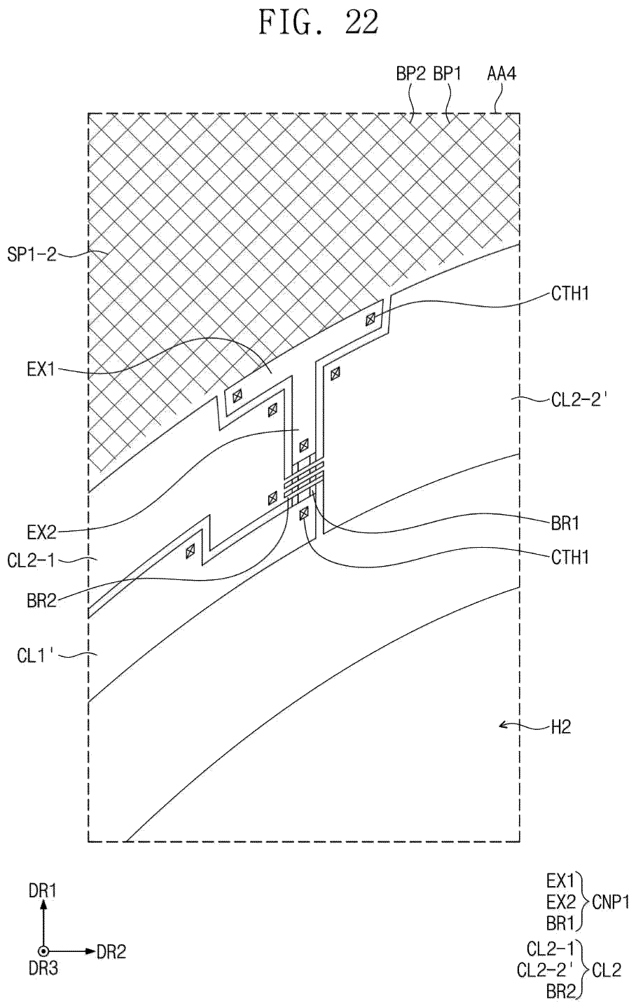

FIG. 21 is a view illustrating a configuration of a first connecting line and a second connecting line around a first hole according to some embodiments of the present disclosure. FIG. 22 is a view illustrating a configuration of a first connecting line and a second connecting line around a second hole according to some embodiments of the present disclosure.

The following description will be focused on the difference between the components illustrated in FIGS. 21 and 22 and the components illustrated in FIGS. 13 and 19.

Referring to FIGS. 21 and 22, although the first connecting line CL1 in FIGS. 13 and 19 extends to the opposite sides with respect to the second extension EX2, the first connecting line CL1′ illustrated in FIGS. 21 and 22 may extend to one side with respect to a second extension EX2.

In FIGS. 13 and 19, the second-first connecting line CL2-1 and the second-second connecting line CL2-2, which are adjacent to the first connecting part CNP1, may have shapes symmetrical to each other with respect to the first connecting part CNP1. However, in FIGS. 21 and 22, a second-first connecting line CL2-1 and a second-second connecting line CL2-2′ that are adjacent to a first connecting part CNP1 may have shapes asymmetrical to each other with respect to the first connecting part CNP1.

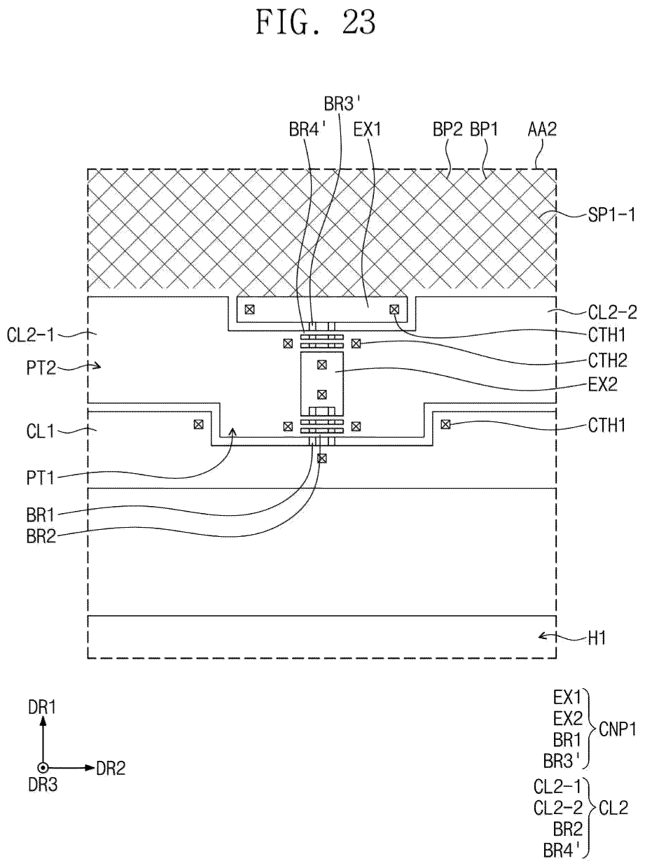

FIG. 23 is a view illustrating a configuration of a first connecting part and a second connecting line according to some embodiments of the present disclosure.

The following description will be focused on the difference between the components illustrated in FIG. 23 and the components illustrated in FIG. 13.

Referring to FIG. 23, the first connecting part CNP1 may further include third bridge lines BR3′ that are located between a first extension EX1 and a second extension EX2 and that connect the first extension EX1 and the second extension EX2. The second connecting line CL2 may further include fourth bridge lines BR4′ that are located between a second-first connecting line CL2-1 and a second-second connecting line CL2-2 and that connect the second-first connecting line CL2-1 and the second-second connecting line CL2-2.

The third bridge lines BR3′ may extend in the first direction DR1 and may be arranged in the second direction DR2. Depending on the above-described multi-layer structure, the third bridge lines BR3′ may extend from lower electrodes LCT of the first and second extensions EX1 and EX2.

The fourth bridge lines BR4′ may extend in the second direction DR2 and may be arranged in the first direction DR1. The fourth bridge lines BR4′ may extend to cross the third bridge lines BR3′ while being insulated from the third bridge lines BR3′. The fourth bridge lines BR4′ may be located in a layer above the third bridge lines BR3′. Depending on the above-described multi-layer structure, the fourth bridge lines BR4′ may extend from upper electrodes UCT of the second-first and second-second connecting lines CL2-1 and CL2-2.

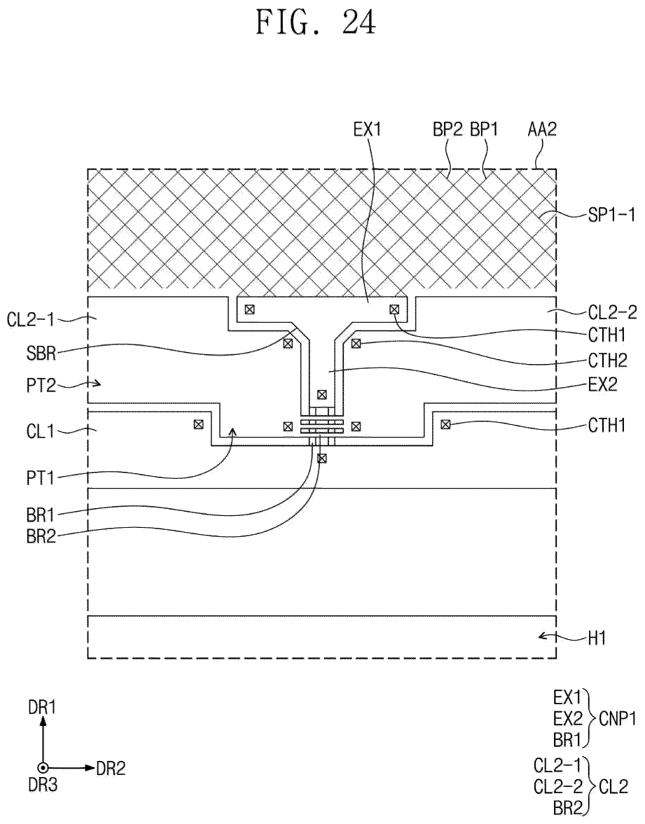

FIG. 24 is a view illustrating a configuration of a first connecting part according to some embodiments of the present disclosure.

The following description will be focused on the difference between the components illustrated in FIG. 24 and the components illustrated in FIG. 13.

Referring to FIG. 24, a boundary portion SBR between a first extension EX1 and a second extension EX2 may have an inclined surface that is inclined with respect to the first direction DR1 or the second direction DR2.

According to the embodiments of the present disclosure, each of the first and second connecting parts arranged around the hole may include the first extension and the second extension that form the shape of “T”. The first extension having a greater width in the second direction than the second extension may be connected to the corresponding first sensing part. Accordingly, the first extension and the corresponding first sensing part may be relatively more robustly connected with each other.

In addition, the second-first connecting line and the second-second connecting line may be located adjacent to each other and connected with each other with the second extension therebetween, in which the second extension has a smaller width in the second direction than the first extension. Accordingly, the gap between the second-first connecting line and the second-second connecting line may be reduced, and thus the resistance of the second connecting line may be decreased.

While aspects of some embodiments of the present disclosure have been described with reference to embodiments thereof, it will be apparent to those of ordinary skill in the art that various changes and modifications may be made thereto without departing from the spirit and scope of the present disclosure as set forth in the following claims, and their equivalents.

What is claimed is:

1. An input sensing part comprising:
a first-first sensing part and a first-second sensing part arranged in a first direction with a hole therebetween;
two second sensing parts arranged in a second direction crossing the first direction with the hole therebetween and connected with each other;
a first connecting line between each of the first-first and first-second sensing parts and the hole, the first connecting line connected to the first-first and first-second sensing parts by extending along the hole; and
a connecting part between the first-first sensing part and the first connecting line to connect the first-first sensing part to the first connecting line,
wherein the connecting part includes:
a first extension connected to a edge of the first-first sensing part by extending along the edge of the first-first sensing part; and
a second extension connected to the first connecting line by extending from a portion of the first extension toward the first connecting line.

2. The input sensing part of claim 1, wherein based on an extension direction of the first extension, the first extension has a greater width than the second extension.

3. The input sensing part of claim 2, wherein the first extension extends in the second direction, and the second extension extends in the first direction.

4. The input sensing part of claim 2, wherein the first extension extends in a curved direction with respect to the second direction, and the second extension extends in the first direction.

5. The input sensing part of claim 1, wherein the connecting part further includes at least one first bridge line between the second extension and the first connecting line and connecting the second extension and the first connecting line.

6. The input sensing part of claim 5, wherein each of the first connecting line and the second extension includes:
a lower electrode; and
an upper electrode on the lower electrode and connected to the lower electrode, and
wherein the at least one first bridge line extends from the lower electrode of the second extension and the lower electrode of the first connecting line.

7. The input sensing part of claim 5, further comprising:
a second connecting line between each of the second sensing parts and the hole and connected to the two second sensing parts by extending along the hole to cross the connecting part while being insulated from the connecting part,
wherein the second connecting line includes:
a second-first connecting line and a second-second connecting line arranged with the connecting part therebetween; and
at least one second bridge line connecting the second-first connecting line and the second-second connecting line, and
wherein the at least one second bridge line extends to cross the at least one first bridge line while being insulated from the at least one first bridge line.

8. The input sensing part of claim 7, wherein each of the second-first connecting line and the second-second connecting line includes:
a lower electrode; and
an upper electrode on the lower electrode and connected to the lower electrode, and
wherein the at least one second bridge line extends from the upper electrode of the second-first connecting line and the upper electrode of the second-second connecting line.

9. The input sensing part of claim 7, wherein based on the second direction, a gap between the second-first connecting line and the second-second connecting line is in a range of 60 micrometers to 100 micrometers.

10. The input sensing part of claim 7, wherein the second-first connecting line includes:
a first portion between the first extension and the first connecting line; and
a second portion between a edge of the first-first sensing part not being connected to the first extension and the first connecting line and formed with a step with respect to the first portion,
wherein one side of the first connecting line facing the first and second portions has a step shape corresponding to a step shape defined by the first and second portions, and
wherein based on the first direction, the first portion has a same width as the second portion.

11. The input sensing part of claim 10, wherein based on the first direction, a distance between one side of the first extension connected to the edge of the first-first sensing part and one side of the first portion facing the first extension is defined as a first distance,
wherein based on the first direction, a distance between one side of the first connecting line facing the first portion and one side of the second portion facing the first connecting line is defined as a second distance, and
wherein the first distance and the second distance are equal to each other.

12. The input sensing part of claim 10, wherein the second-first connecting line and the second-second connecting line adjacent to the connecting part have shapes symmetrical to each other with respect to the connecting part.

13. The input sensing part of claim 10, wherein the second-first connecting line and the second-second connecting line adjacent to the connecting part have shapes asymmetrical to each other with respect to the connecting part.

14. The input sensing part of claim 7, wherein the connecting part further includes at least one third bridge line between the first extension and the second extension and connected to the first extension and the second extension, and
wherein the second connecting line further includes at least one fourth bridge line between the second-first connecting line and the second-second connecting line and connected to the second-first connecting line and the second-second connecting line, the at least one fourth bridge line being extending to cross the third bridge line while being insulated from the third bridge line.

15. The input sensing part of claim 1, wherein the first connecting line extends to opposite sides with respect to the second extension.

16. The input sensing part of claim 1, wherein the first connecting line extends to one side with respect to the second extension.

17. The input sensing part of claim 1, further comprising:
a first sensing part in the first direction with the first-second sensing part; and
an extending pattern extending from the first-second sensing part and the first sensing part in the first direction,
wherein based on the second direction, the extending pattern and the first extension have a same width.

18. The input sensing part of claim 1, wherein the first-first sensing part includes a plurality of mesh lines to have a mesh shape, and
wherein the first extension is connected to five to twenty mesh lines.

19. An input sensing part comprising:
a first-first sensing part and a first-second sensing part arranged in a first direction with a hole therebetween;
two second sensing parts arranged in a second direction crossing the first direction with the hole therebetween and connected with each other;
a first connecting line between each of the first-first and first-second sensing parts and the hole, the first connecting line connected to the first-first and first-second sensing parts by extending along the hole; and
a connecting part between the first-first sensing part and the first connecting line to connect the first-first sensing part to the first connecting line,
wherein the connecting part has a shape of “T”.

20. A display device comprising:
a display panel; and
an input sensing part on the display panel,
wherein a hole is continuously defined in the display panel and the input sensing part,
wherein the input sensing part includes:
a first-first sensing part and a first-second sensing part arranged in a first direction with the hole therebetween;
two second sensing parts arranged in a second direction crossing the first direction with the hole therebetween and connected with each other;
a first connecting line between each of the first-first and first-second sensing parts and the hole, the first connecting line connected to the first-first and first-second sensing parts by extending along the hole; and
a connecting part between the first-first sensing part and the first connecting line to connect the first-first sensing part to the first connecting line, and
wherein the connecting part includes:
a first extension connected to a edge of the first-first sensing part by extending in the second direction; and
a second extension connected to the first connecting line by extending from a portion of the first extension in the first direction.
